(19) United States
(12) Patent Application Publication
(10) Pub. No.: US 2019/0095004 A1
(43) Pub. Date: Mar. 28, 2019

(54) FINGERPRINT SENSOR MODULE AND METHOD OF MANUFACTURING SAME

(71) Applicant: CRUCIALTEC CO., LTD., Seongnam-si (KR)

(72) Inventors: Dong Nam SON, Busan (KR); Ju Sung KIM, Asan-si (KR)

(21) Appl. No.: 16/082,776

(22) PCT Filed: Jun. 20, 2017
(86) PCT No.: PCT/KR2017/006488

§ 371 Date: Sep. 6, 2018

(30) Foreign Application Priority Data
Jun. 21, 2016 (KR) 10-2016-0077432
Jun. 16, 2017 (KR) 10-2017-0076408

(51) Int. Cl. G06F 3/044; H03K 17/96; H01L 21/56

(52) U.S. Cl. CPC G06F 3/044; G06F 2203/04103; H01L 21/565; H03K 17/962

(57) ABSTRACT

A fingerprint sensor module and a method of manufacturing same, the fingerprint sensor module including: a sensor package provided on a top portion of a base substrate, and having a sensor part electrically connected to the base substrate and sensing biometric information and the sensor package having an encapsulation part for covering the base substrate and the sensor part; and a cap coupled to the circumference of a side surface of the sensor package and forming an insertion space part.

### CROSS-REFERENCE TO RELATED APPLICATIONS

This application is the National Stage Entry of International Patent Application No. PCT/KR/2017/006488, filed on Jun. 20, 2017, and claims priority from and the benefit of Korean Patent Application No. 10-2016-0077432, filed on Jun. 21, 2016, and Korean Patent Application No. 10-2017-0076408, filed Jun. 16, 2017, all of which are hereby incorporated by reference for all purposes as if set forth herein.

### BACKGROUND

### Field

Exemplary embodiments of the present invention relates to a fingerprint sensor module and a method of manufacturing the same, and more particularly, to a fingerprint sensor module having an overall keycap shape and including a cover unit in the form of an under-glass, which has a simple external appearance and an improved waterproof property, and a method of manufacturing the same.

### Discussion of the Background

Recently, use of internet banking, which enables users to perform banking operations through the Internet by using electronic devices such as a mobile phone, a smartphone, a personal digital assistant (PDA), a notebook, a desktop computer, and a tablet PC, have been increasing every day.

Internet banking enables users to perform various banking operations, such as remittance, confirmation of deposit and withdrawal history, account creation, an automatic transfer, and a loan, through personal authentication. Electronic devices capable of accessing the Internet require a locking device.

Generally, an electronic device maintains a locked state by using a password function. However, when a user of the electronic device forgets a unique password, the user may not use the electronic device.

In addition, while a user having authority for use inputs a password thereof, the password may be exposed to surrounding people and may be stolen through a hacking program. Thus, significant security vulnerability may be present in an electronic device having a password function.

Recently, fingerprint recognition has been applied to electronic devices in order to supplement such a method and improve a locking effect.

In an example, a fingerprint sensor may be implemented to be integrated into a physical function key.

The fingerprint sensor is a sensor configured to sense a fingerprint of a human being. A user registration and an authentication process may be performed through the fingerprint sensor, thereby protecting data stored in an electronic device and preventing a security accident.

The fingerprint sensor may be manufactured in the form of a module including peripheral components or structures, and thus, may be effectively mounted on various electronic devices.

The fingerprint sensor may convert an individual fingerprint into a code by using features of the individual fingerprint. In this case, since the converted and generated code has a very low theoretical probability of being registered to match a fingerprint code of other people, user authentication using a fingerprint may become common.

FIG. 1 is an exemplary view illustrating a notebook equipped with a conventional fingerprint sensor.

As shown in FIG. 1, a notebook 10 may include a display unit 20 and a body unit 30.

The display unit 20 and the body unit 30 may be rotatably hinged to each other, and thus, be folded to come into close with each other. Alternatively, the display unit 20 may be selectively fixed in a state of being inclined at a certain angle from the body unit 30.

The display unit 20 is a unit on which a screen is displayed. A user may check various documents, Internet data, or the like through the display unit 20.

The body unit 30 may include a keyboard unit 31 and a fingerprint recognition unit 32. The keyboard unit 31 may be provided with a plurality of keycaps on which characters, numbers, symbols, and the like are marked, and thus, may be used as an input unit.

Meanwhile, the fingerprint recognition unit 32 is installed in the body unit 30 together with the keyboard unit 31. A user performs use authentication through the fingerprint recognition unit 32.

However, when the above-described fingerprint recognition unit 32 is installed in the body unit 30, the fingerprint recognition unit 32 should be installed in a space other than the keyboard unit 31. That is, the body unit 30 should have a separate installation space for installing the fingerprint recognition unit 32. As a result, there are problems in that a product size of the notebook 10 to be manufactured is increased and a design of the body unit 30 is not simple.

### SUMMARY

In order to solve the above problems, the present invention is directed to providing a fingerprint sensor module having a keycap shape and a method of manufacturing the same.

In order to achieve the object of the present invention, an exemplary embodiment of the present invention provides a fingerprint sensor module including: a sensor package which includes a sensor provided on an upper portion of a base substrate, electrically connected to the base substrate, and configured to sense biometric information and including an encapsulation part configured to cover the base substrate and the sensor; and a cap which is coupled to a side circumference of the sensor package and forms an insertion space part.

In an exemplary embodiment of the present invention, a side surface of the base substrate may be inclined such that a length from a virtual central axis of the base substrate is gradually increased from a lower portion of the base substrate to an upper portion of the base substrate.

In an exemplary embodiment of the present invention, a stepped portion may be formed in the encapsulation part.

In an exemplary embodiment of the present invention, the cap and the base substrate may be coupled in a state in which a lower portion of the base substrate partially protrudes from the cap to the insertion space part.

In an exemplary embodiment of the present invention, the cap may be made of a conductive material.

In an exemplary embodiment of the present invention, the cap may include a fixing part which is coupled to the sensor package; and a supporting part which is bent from the fixing part, forms the insertion space part, and supports the fixing part.

An exemplary embodiment of the present invention provides a fingerprint sensor module including: a base substrate; a sensor which is provided on an upper portion of the base substrate, is electrically connected to the base substrate, and senses biometric information; and an encapsulation part which covers the base substrate and the sensor, wherein the encapsulation part has a keycap shape and forms an insertion space part below the base substrate.

In an exemplary embodiment of the present invention, the encapsulation part may include a cover member which covers an upper surface of the base substrate and the sensor and a vertical member which extends downward from an edge of the cover member and covers a side surface of the base substrate, wherein the vertical member forms the insertion space part below the base substrate.

In an exemplary embodiment of the present invention, fixing holes may be formed at preset intervals along a circumference of the vertical member.

In an exemplary embodiment of the present invention, guide protrusions each having a width corresponding to each of the fixing holes may be formed on the base substrate.

In an exemplary embodiment of the present invention, a height of the encapsulation part may be greater than a height in which the base substrate and the sensor are coupled.

An exemplary embodiment of the present invention provides a method of manufacturing a fingerprint sensor module, the method including: a) manufacturing a sensor package; and b) coupling the sensor package and a cap.

In an exemplary embodiment of the present invention, operation a) may include forming an inclination at a side surface of a base substrate and forming a stepped portion in an encapsulation part provided on an upper portion of the base substrate, wherein the side surface of the base substrate is inclined such that a length from a virtual central axis is gradually increased from a lower portion of the base substrate to the upper portion of the base substrate.

In an exemplary embodiment of the present invention, operation b) may include fixing the sensor package to a molding die unit, supplying a molding material into the molding die unit from a supply unit to mold the cap, and coupling a side circumference of the sensor package and the cap.

Effects of the fingerprint sensor module and the method of manufacturing the same according to the present invention described above will be described as follows.

According to the present invention, the fingerprint sensor module having a keycap shape can be provided in a keyboard unit. Thus, an electronic device such as a notebook does not need to have a separate space for installing a fingerprint recognition unit. As a result, a manufacturing process of the electronic device can be simplified, and the electronic device can be miniaturized.

It should be understood that the effects of the present invention are not particularly limited to those described above, and the present invention includes all effects that can be deduced from the detailed description of the invention or the configurations of the invention described in the claims.

### DESCRIPTION OF THE DRAWINGS

The accompanying drawings, which are included to provide a further understanding of the inventive concept, and are incorporated in and constitute a part of this specification illustrate exemplary embodiments of the inventive concept, and, together with the description, serve the explain principles of the inventive concept.

FIG. 1 is an exemplary view illustrating a notebook equipped with a conventional fingerprint sensor.

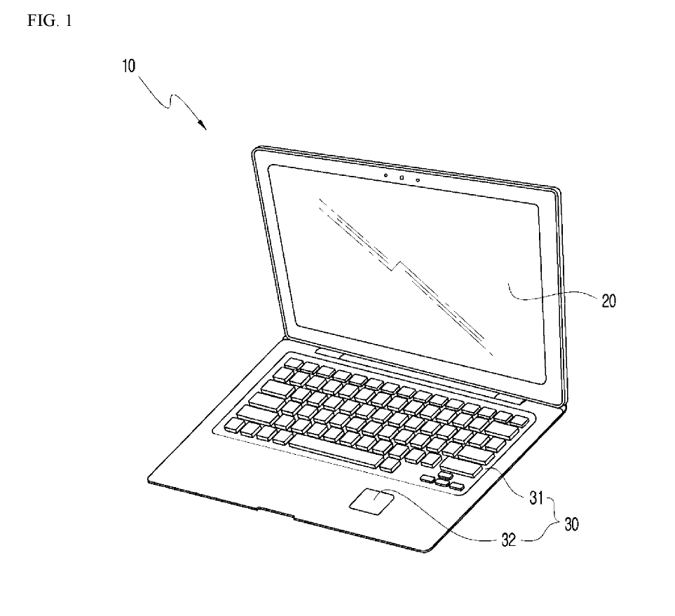

FIG. 2 is an exemplary view illustrating a notebook equipped with a fingerprint sensor module according to an exemplary embodiment of the present invention.

FIG. 3 is a perspective view illustrating the fingerprint sensor module according to the exemplary embodiment of the present invention.

FIG. 4 is a cross-sectional view illustrating the fingerprint sensor module according to the exemplary embodiment of the present invention.

FIG. 5 is an exemplary view illustrating a process of manufacturing a fingerprint sensor module according to an exemplary embodiment of the present invention.

FIG. 6 is a flowchart of the process of manufacturing the fingerprint sensor module according to the exemplary embodiment of the present invention.

FIG. 7 is a perspective view illustrating a fingerprint sensor module according to another exemplary embodiment of the present invention.

FIG. 8 is a cross-sectional view taken along line I-I of FIG. 7.

FIG. 9 is a cross-sectional view taken along line II-II of FIG. 7.

### DETAILED DESCRIPTION

Hereinafter, the present invention will be described with reference to the accompanying drawings. However, it is to be noted that the present invention is not limited to the example embodiments but can be realized in various other ways. In the drawings, certain parts not directly relevant to the description are omitted to enhance the clarity of the present invention, and like reference numerals denote like parts throughout the whole document.

Throughout the whole document, the terms “connected to” or “coupled to” are used to designate a connection or coupling of one element to another element and include both a case where an element is “directly connected or coupled to” another element and a case where an element is “indirectly connected or coupled to” another element via still another element. In addition, unless explicitly described to the contrary, “comprising” or “including” any components will be understood to imply the inclusion of other components rather than the exclusion of other components.

Hereinafter, exemplary embodiments of the present invention will be described in detail with reference to the accompanying drawings.

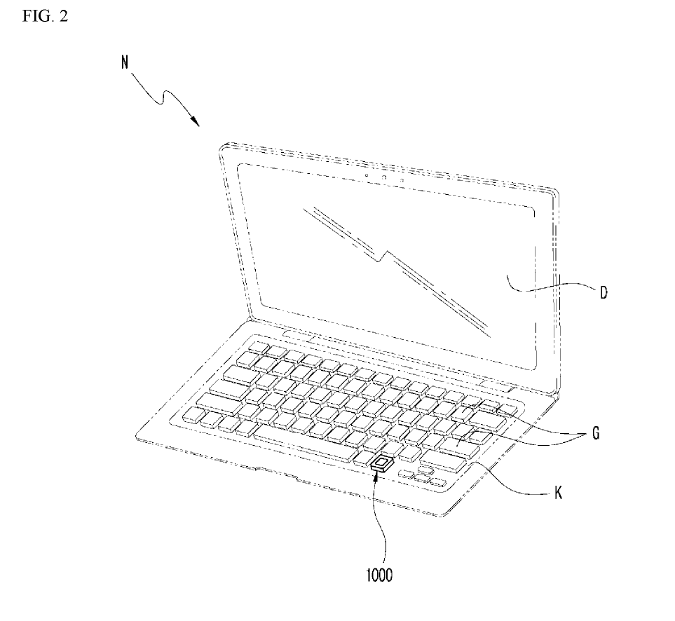

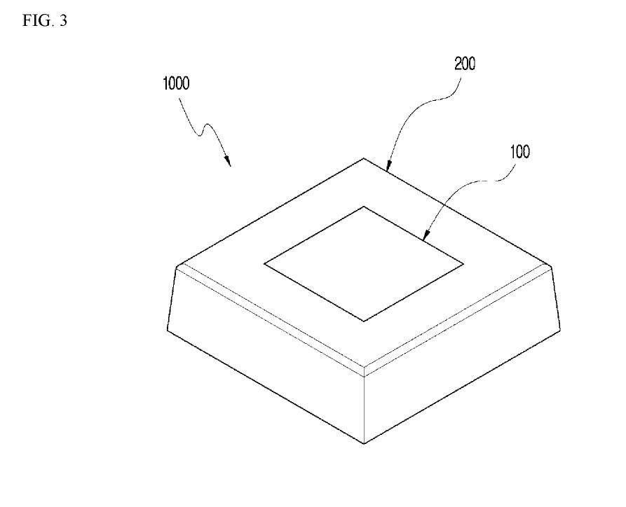

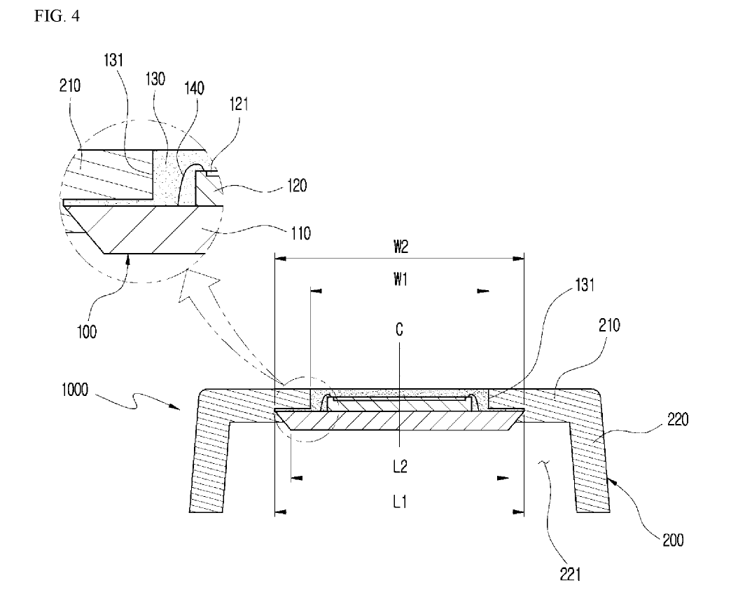

FIG. 2 is an exemplary view illustrating a notebook equipped with a fingerprint sensor module according to an exemplary embodiment of the present invention. FIG. 3 is a perspective view illustrating the fingerprint sensor module according to the exemplary embodiment of the present invention. FIG. 4 is a cross-sectional view illustrating the fingerprint sensor module according to the exemplary embodiment of the present invention.

As shown in FIGS. 2 to 4, a fingerprint sensor module 1000 may be applied to various electronic devices. In the present invention, a type in which the fingerprint sensor module 1000 is applied to a notebook N will be described as an example.

The notebook N may include a display unit D and a keyboard unit K.

The display unit D is a unit on which a screen is displayed. A user may check various documents, internet data, or the like through the display unit D.

The keyboard unit K is hinged to the display unit D and is rotatable. A plurality of keycaps G are provided in the keyboard unit K. A user may use the keycaps G as an input part.

Here, the keycap G is configured to distinguish each key from other keys in the keyboard unit K of the notebook N. A character, a number, a symbol, or the like corresponding to each key is marked on an upper surface of the keycap G.

The above-described keycap G, on which the character, the number, the symbol, or the like used in the keyboard unit K is marked, maintains a state of being lifted by elasticity. When the keycap G is pressed by a finger, the keycap G is lowered, and contact of a switch is made. When the finger is lifted from the keycap G, the keycap G is lifted again by an elastic member therein and the contact of the switch is released. Therefore, a user may selectively press the keycap G to input the character, the number, the symbol, or the like of the keycap G.

Meanwhile, the fingerprint sensor module 1000 having the same shape as the keycap G may be provided in the notebook N. The fingerprint sensor module 1000 is installed in the keyboard unit K together with the keycap G. Here, the fingerprint sensor module 1000 may be elevated like the keycap G or may be fixedly installed in the keyboard unit K in a state of being not elevated unlike the keycap G.

The above-described fingerprint sensor module 1000 has a configuration for measuring biometric information of a user rather than a configuration for inputting a key. Hereinafter, for convenience, it will be described that the fingerprint sensor module 1000 recognizes a fingerprint of a user.

The fingerprint sensor module 1000 may be manufactured in a three-dimensional shape deviating from a general shape in which the fingerprint sensor module 1000 is mounted on an electronic device through an existing semiconductor process. In an example, the fingerprint sensor module 1000 may have the same three-dimensional shape as the keycap G and may be installed in the keyboard unit K together with the keycap G. Thus, when a fingerprint recognition unit is installed in the conventional notebook, a body unit does not need to have a separate space for installing the fingerprint recognition unit. Therefore, an electronic device may be designed with a simple design.

Referring to FIGS. 3 and 4, the fingerprint sensor module 1000 may include a sensor package 100 and a cap 200.

The sensor package 100 may be configured to recognize a fingerprint of a user and may include a base substrate 110, a sensor 120, and an encapsulation part 130.

The base substrate 110 may be a substrate on which the sensor 120 or the like is mounted and through which electrical signal information is transmitted.

The sensor 120 may be provided on the base substrate 110, and a sensor part 121 may be provided on an upper portion of the sensor 120.

The sensor part 121 may sense biometric information, for example, fingerprint information.

The sensor part 121 may include sensing pixels. The sensing pixels may have various shapes. For example, the sensing pixels may have sensing regions arranged in an array form.

In addition, the sensor 120 may be a capacitive fingerprint sensor. The sensor part 121 may form capacitance together with a user's finger. In this case, each pixel of the sensor part 121 may form capacitance together with the user's finger. The sensor part 121 may measure a magnitude of capacitance to sense a difference in capacitance according to a fingerprint of the user's finger on an upper portion of a corresponding pixel.

Accordingly, the sensor 120 may sense a change in capacitance according to access or movement of the user's finger. The sensor 120 may sense the fingerprint of the user's finger which touches the sensor 120 or is closely spaced apart from the sensor 120.

In addition, the sensor 120 may be a biometric trackpad (BTP) which has a fingerprint sensing function of sensing a fingerprint and a pointer operation function. Furthermore, the sensor 120 may have a pointer operation function of sensing input information or capacitance according to access or movement of the user's finger and moving a pointer such as a cursor based on the movement.

The above-described configuration of the sensor part 121 is merely an example. The present invention is not limited to the type including the sensing pixels described above, and the sensor part 121 may be formed in other types.

Meanwhile, the encapsulation part 130 may be provided on the base substrate 110 to cover the sensor 120. The encapsulation part 130 may cover the base substrate 110 and the sensor 120 to protect various electrical components. The encapsulation part 130 may be made of an epoxy molding compound, but the present invention is not limited thereto.

The sensor 120 may be electrically connected to the base substrate 110. The sensor 120 and the base substrate 110 may be electrically connected through various methods. Hereinafter, it will be described that the sensor 120 and the base substrate 110 are electrically connected through a bonding wire 140.

The sensor 120 and the base substrate 110 may be electrically connected through the bonding wire 140. The bonding wire 140 may be covered by the encapsulation part 130. Here, the bonding wire 140 may be a gold wire, but the present invention is not limited thereto.

The sensor package 100 may further include a driving IC (not shown). The driving IC is configured to transmit a driving signal to a user's finger. That is, after the driving signal transmitted from the driving IC passes through the user's finger (object), signal information is transmitted to the sensor 120 so that the sensor 120 reads fingerprint information of the user's finger.

A cover unit (not shown) may be further provided on an upper surface of the encapsulation part 130.

Here, the cover unit performs various functions such as a function of implementing a color in the sensor package 100, a function of reinforcing strength of the sensor package 100, and the like. The cover unit may be provided on an upper portion of the encapsulation part 130.

The cover unit may be made of a material having excellent durability and external appearance. For example, the cover unit may include at least one selected from glass, sapphire, zirconium, and a transparent resin. When the cover unit is made of the glass, the cover unit may include various glass substrates such as a soda-lime glass substrate, an alkali-free glass substrate, and a tempered glass substrate. Acrylic or the like may be included as the transparent resin.

In an example, the cover unit may include a primer layer, a color paint layer, and a protective film layer. In the cover unit, the primer layer, the color coating layer, and the protective film layer may be sequentially formed.

The primer layer may be provided on the upper portion of the encapsulation part 130 to connect the color paint layer. The color paint layer may perform a function of implementing colors.

The protective film layer may be an ultraviolet (UV) protective film or a ceramic coating layer including ceramic. The present invention is not limited to a configuration of the primer layer, the color paint layer, and the protective film layer, and the cover unit may also have various configurations.

Meanwhile, the cap 200 supports the sensor package 100 so that the fingerprint sensor module 1000 has various three-dimensional shapes.

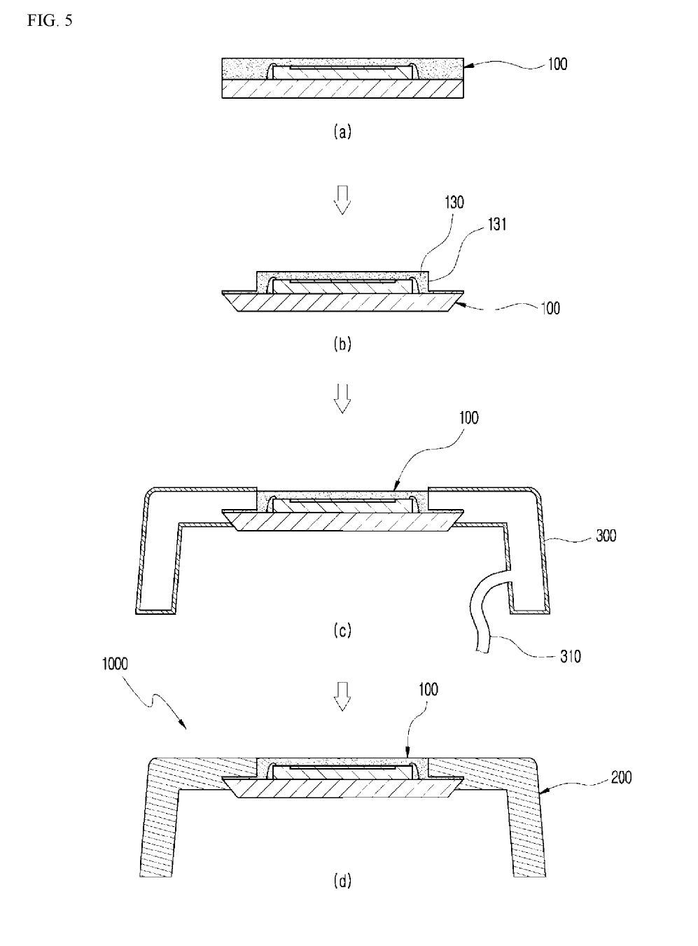

The cap 200 is coupled to the sensor package 100. Specifically, the cap 200 is coupled along a side circumference of the sensor package 100. That is, in the fingerprint sensor module 1000, the sensor package 100 and the cap 200 may be coupled by molding the cap 200 in a state in which the sensor package 100 is fixed to a molding die unit 300 (see FIG. 5) for molding the cap 200. Here, it will be described that the fingerprint sensor module 1000 according to the exemplary embodiment has the same shape as the keycap G.

When the sensor package 100 and the cap 200 are coupled, the base substrate 110 is coupled to the cap 200 in a state in which a side surface of the base substrate 110 is inclined. That is, the side surface of the base substrate 110 is inclined such that a length from a virtual central axis C of the base substrate 110 is gradually increased from a lower portion of the base substrate 110 to an upper portion of the base substrate 110.

The base substrate 110 has a trapezoidal shape in which a length L1 of an upper side thereof is greater than a length L2 of a lower side thereof when viewed in a cross section of the fingerprint sensor module 1000 of FIG. 4. That is, the side surface of the base substrate 110 is inclined.

Therefore, even when a user presses the sensor package 100 in a state in which the user places a finger on an upper surface of the sensor package 100, the side surface of the sensor package 100 may be inclined, thereby preventing the sensor package 100 from deviating in a downward direction from the cap 200.

On the other hand, a stepped portion 131 is formed in the encapsulation part 130. That is, the encapsulation part 130 is provided on an upper surface of the base substrate 110. The encapsulation part 130 is formed to have a certain thickness and the same size as the upper surface of the base substrate 110. Then, the stepped portion 131 is formed such that a distance between the sensor 120 and a side surface of the encapsulation part 130 is decreased. In other words, upper and lower surfaces of the encapsulation part 130 have different cross sections. That is, the stepped portion 131 is formed in the encapsulation part 130 such that a length W1 of the upper surface of the encapsulation part 130 is smaller than a width W2 of the lower surface of the encapsulation part 130.

As described above, since the stepped portion 131 is formed in the encapsulation part 130, the coupling area, in which the encapsulation part 130 and the cap 200 are coupled in a state of being in contact with each other, may be widened so that the encapsulation part 130 and the cap 200 may be strongly coupled. Here, the present invention is not limited to a shape according to an exemplary embodiment, and the encapsulation part 130 may have various shapes capable of improving coupling with the cap 200.

Here, the cap 200 may be made of a conductive material. The cap 200 prevents the sensor 120 from being damaged by static electricity which is instantaneously generated when a user's finger touches the sensor package 100. That is, the cap 200 made of the conductive material performs an electrostatic discharge (ESD) function

Since the stepped portion 131 is formed in the encapsulation part 130, the distance between the cap 200 and the sensor 120 may be decreased so that static electricity instantaneously generated when a user's finger touches the sensor package 100 may be effectively guided to the cap 200. Here, the present invention is not necessarily limited to the conductive material, but the cap 200 may be made of various materials such as an insulating resin material.

The cap 200 may have a different color from the sensor package 100. The cap 200 clearly distinguishes a boundary with the sensor package 100. Accordingly, a user may accurately place a finger on the sensor package 100 in which fingerprint recognition is performed.

The cap 200 may include a fixing part 210 and a supporting part 220.

The fixing part 210 is coupled to the sensor package 100.

The supporting part 220 is bent from the fixing part 210 to form an insertion space part 221. A lower surface of the supporting part 220 is coupled to the keyboard unit K to support the fixing part 210.

Here, when the sensor package 100 is coupled to the fixing part 210, the base substrate 110 is coupled to the fixing part 210 in a state in which a lower portion of the base substrate 110 partially protrudes from a lower surface of the fixing part 210 to the insertion space part 221. This is to prevent a lower surface of the base substrate 110 from being covered with a molding material due to flashing in which the molding material is discharged through a gap of the molding die unit 300 and is solidified when the cap 200 is molded.

Thus, when the base substrate 110 and a flexible substrate (not shown) are coupled, defective coupling caused by flashing can be prevented. Therefore, fingerprint information transmitted from the sensor 120 may be transmitted to a main board (not shown) through the base substrate 110 and the flexible substrate without electrical defects.

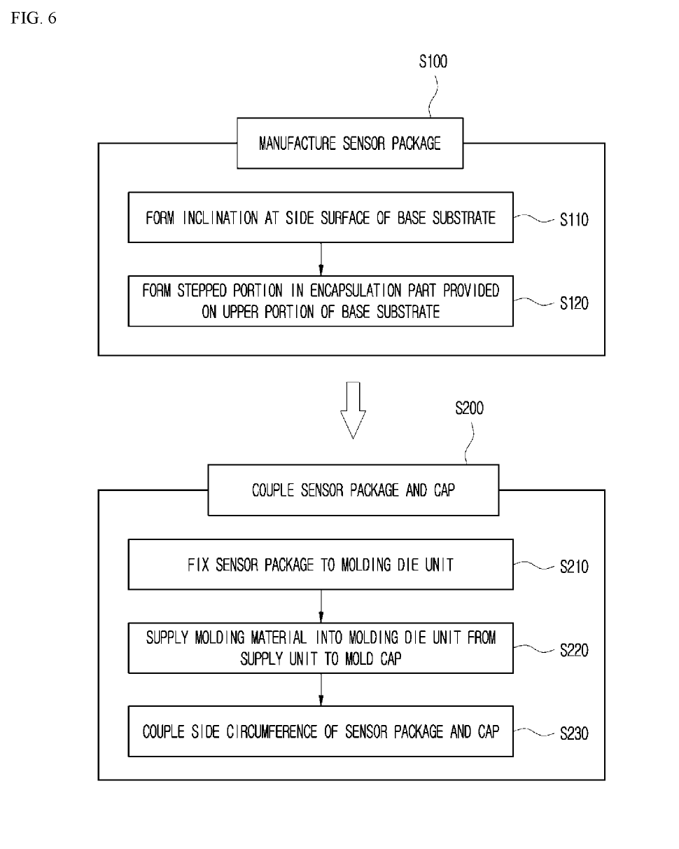

FIG. 5 is an exemplary view illustrating a process of manufacturing a fingerprint sensor module according to an exemplary embodiment of the present invention. FIG. 6 is a flowchart of the process of manufacturing the fingerprint sensor module according to the exemplary embodiment of the present invention. Elements denoted by the same reference numerals as the reference numerals shown in FIGS. 2 to 4 have the same functions as elements denoted by the reference numerals shown in FIGS. 2 to 4, and detailed descriptions of each of the elements will be omitted.

A method of manufacturing a fingerprint sensor module 1000 will be described with reference to FIGS. 5 and 6. First, a sensor package 100 is manufactured (S100).

Here, an inclination is formed at a side surface of a base substrate 110. In this case, the inclination is formed at the side surface of the base substrate 110 such that a length from a virtual central axis C of the base substrate 110 is gradually increased from a lower portion of the base substrate 110 to an upper portion of the base substrate 110 (S110).

Next, a stepped portion 131 is formed in an encapsulation part 130 provided on the upper portion of the base substrate 110. In this case, the stepped portion 131 is formed in the encapsulation part 130 such that a length W1 of an upper surface of the encapsulation part 130 is smaller than a width W2 of a lower surface of the encapsulation part 130 (S120).

After that, a cap 200 is coupled to the sensor package 100, in which the inclination is formed at the side surface of the base substrate 110, and the stepped portion 131 is formed in the encapsulation part 130 (S200).

Specifically, first, the sensor package 100 is fixed to a molding die unit 300 (S210).

Next, in a state in which the sensor package 100 is fixed to the molding die unit 300, a molding material is supplied into the molding die unit 300 to mold the cap 200. The molding die unit 300 is connected to a supply unit 310. The molding material fills an inner space of the molding die unit 300 through the supply unit 310 and then is cured and molded into the cap 200 (S220).

Here, the supply unit 310 connected to the molding die unit 300 may be positioned on an upper portion or a lower portion of the molding die unit 300. A position of the supply unit 310 connected to the molding die unit 300 is not limited to a specific position. A burr, in which unnecessary portions are molded together with an object to be molded during molding, may be generated in a portion where the molding die unit 300 and the supply unit 310 are connected. A separate removal operation should be performed on the burr for quality of a product. Therefore, the supply unit 310 to be connected to the molding die unit 300 is connected to an inner surface of the molding die unit 300, in which a supporting part 220 is formed. It is preferable that the supply unit 310 is configured to prevent a burr spot from being exposed to the outside in a state in which the fingerprint sensor module 1000 is installed in a keyboard unit K.

The cap 200 may be coupled to a side circumference of the sensor package 100, and the fingerprint sensor module 1000 may be manufactured (S230).

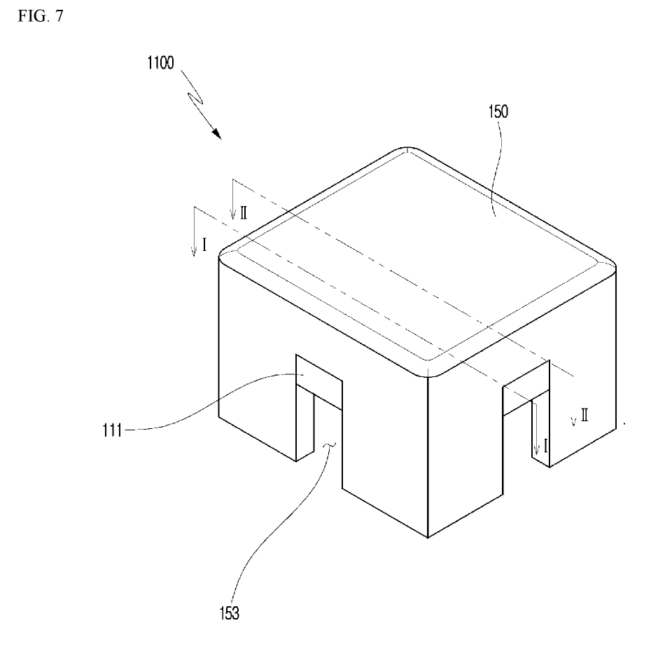

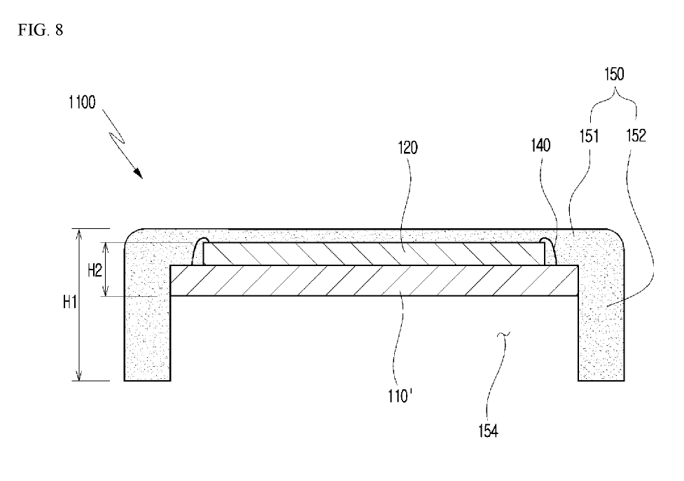

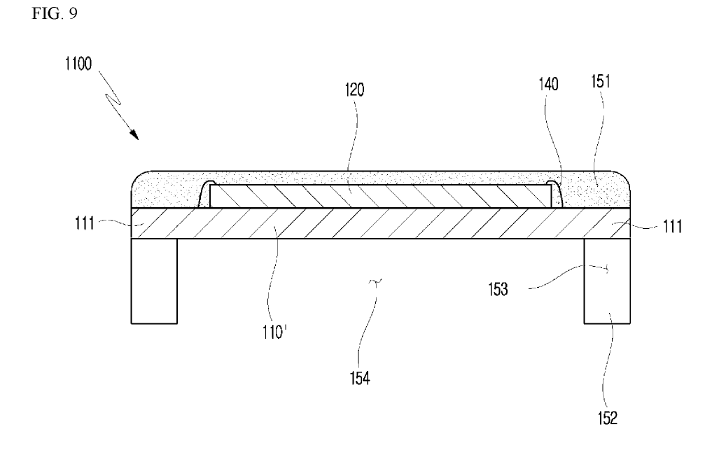

FIG. 7 is a perspective view illustrating a fingerprint sensor module according to another exemplary embodiment of the present invention. FIG. 8 is a cross-sectional view taken along line I-I of FIG. 7. FIG. 9 is a cross-sectional view taken along line II-II of FIG. 7. Elements denoted by the same reference numerals as the reference numerals shown in FIGS. 2 to 5 have the same functions as elements denoted by the reference numerals shown in FIGS. 2 to 5, and detailed descriptions of each of the elements will be omitted.

As shown in FIGS. 7 to 9, a fingerprint sensor module 1100 includes a base substrate 110′, a sensor 120, and an encapsulation part 150.

Here, the base substrate 110′ has a different shape from the base substrate 110 according to the previous exemplary embodiment. That is, a side surface of the base substrate 110′ is not inclined from a lower portion of the base substrate 110′ to an upper portion of the base substrate 110′. In other words, the side surface of the base substrate 110′ is perpendicular to a horizontal plane.

The sensor 120 is provided on an upper surface of the base substrate 110′. Here, the sensor 120 senses biometric information, for example, fingerprint information. The base substrate 110′ and the sensor 120 may be electrically connected through a bonding wire 140. Here, the electrical connection between the base substrate 110′ and the sensor 120 is not necessarily limited to the bonding wire 140, and the base substrate 110′ and the sensor 120 may be electrically connected through various types.

Configurations of the base substrate 110′ and the sensor 120 have been described in the exemplary embodiment, and detailed descriptions thereof will be omitted.

Meanwhile, the encapsulation part 150 is configured to cover the base substrate 110′ and the sensor 120. In this case, the encapsulation part 150 has a keycap shape and covers the base substrate 110′ and the sensor 120.

The encapsulation part 150 includes a cover member 151 and a vertical member 152.

The encapsulation part 150 may be integrally coupled to the base substrate 110′ and the sensor 120 through injection molding.

A process of manufacturing the encapsulation part 150 will be described in outline. An upper molding unit (not shown) is disposed on the upper portion of the base substrate 110′, and a lower molding unit (not shown) is disposed on the lower portion of the base substrate 110′ with respect to the base substrate 110′ to which the sensor 120 is coupled.

As described above, a molding material is introduced into the upper molding unit or the lower molding unit in a state in which the base substrate 110′ is disposed between the upper molding unit and the lower molding unit. In this case, the molding material to be introduced into the molding unit is introduced in a state of being heated to a preset temperature. As described above, the molding material filling the molding unit may be molded into the encapsulation part 150 through a curing operation. Here, the upper molding unit molds the cover member 151 of the encapsulation part 150, and the lower molding unit molds the vertical member 152 of the encapsulation part 150.

In this case, the molding material filling the molding unit may include various resin materials. As described above, the molded encapsulation part 150 may be made of an epoxy molding compound, but the present invention is not limited thereto.

A cover unit (not shown) may be additionally provided on an upper surface of the encapsulation part 150 to implement a color of the fingerprint sensor module 1100 or to reinforce strength of the fingerprint sensor module 1100.

The cover member 151 molded by the upper molding unit is disposed on an upper side of the encapsulation part 150 and is configured to cover upper and side surfaces of the sensor 120. The cover member 151 is configured to cover an upper surface of the base substrate 110′ in addition to the sensor 120.

The vertical member 152 molded by the lower molding unit is formed to extend downward from an edge of the cover member 151. The vertical member 152 formed to extend downward from the cover member 151 covers a side surface of the base substrate 110′. In this case, the vertical member 152 extends further downward in a state in which the vertical member 152 covers the side surface of the base substrate 110′ and forms an insertion space part 154 below the base substrate 110′.

The encapsulation part 150 is configured to cover the upper and side surfaces of the base substrate 110′ and the upper and side surfaces of the sensor 120 excluding a lower surface of the base substrate 110′. The encapsulation part 150 is integrally formed with the base substrate 110′ and the sensor 120.

As described above, since the encapsulation part 150 itself has a keycap shape, the fingerprint sensor module 1100 does not require an element such as the cap 200 provided in the fingerprint sensor module 1000 according to the exemplary embodiment. Therefore, a manufacturing process of the fingerprint sensor module 1100 may be simplified, and manufacturing costs may be reduced.

When the fingerprint sensor module 1000 according to the exemplary embodiment and the fingerprint sensor module 1100 according to another exemplary embodiment are fingerprint sensor modules having keycap shapes with the same size, a sensing region of the sensor 120 of the fingerprint sensor module 1100 according to another exemplary embodiment may be wider than that of the fingerprint sensor module 1000 according to the exemplary embodiment, thereby accurately recognizing a fingerprint of a user.

In addition, the fingerprint sensor module 1100 having the keycap shape may be manufactured to have various heights by adjusting a height of the encapsulation part 150. That is, the height of the fingerprint sensor module 1100 is simply adjusted.

Here, a height H1 of the encapsulation part 150 having the keycap shape is greater than a height H2 in which the base substrate 110′ and the sensor 120 are coupled. Therefore, the insertion space part 154 may be formed below the base substrate 110′ in a state in which the encapsulation part 150 is coupled to the base substrate 110′ and the sensor 120.

A flexible substrate (not shown) may be electrically coupled to the base substrate 110′ through the insertion space part 154. Therefore, fingerprint information transmitted from the sensor 120 may be transmitted to a main board (not shown) through the base substrate 110′ and the flexible substrate.

Here, fixing holes 153 may be formed in the vertical member 152. The fixing holes 153 may be formed at preset intervals along a circumference of the vertical member 152. In this case, the shape, size, and number of the fixing holes 153 in the vertical member 152 may be variously formed.

Guide protrusions 111 each having a width corresponding to each of the fixing holes 153 may be formed on the base substrate 110′. Accordingly, when the encapsulation part 150 is molded, the vertical member 152 having the fixing holes 153 may fix the guide protrusions 111.

The guide protrusions 111 formed on the base substrate 110′ guide a molding point where the upper molding unit and the lower molding unit are to be positioned in a process of molding the encapsulation part 150. That is, the upper molding unit and the lower molding unit mold the encapsulation part 150 in a state of being disposed, through the guide protrusions 111, at an accurate position where the encapsulation part 150 is to be molded.

These disclosed embodiments are only exemplary, and the scope of the present invention is not limited by the exemplary embodiments.

Although exemplary embodiments of the present invention have been described for illustrative purposes, those skilled in the art will appreciate that various modifications, additions and substitutions are possible, without departing from the scope and spirit of the invention. Therefore, the above-described exemplary embodiments of the present invention are merely exemplary in all aspects and should not be construed to be limited. For example, each component described to be of a single type can be implemented in a distributed manner. Likewise, components described to be distributed can be implemented in a combined manner.

The scope of the present invention is defined by the following claims and their equivalents rather than by the detailed description of the exemplary embodiments. It should be understood that all modifications and embodiments conceived from the meaning and scope of the claims and their equivalents are included in the scope of the present invention.

1. A fingerprint sensor module comprising:
a sensor package comprising a sensor provided on an upper portion of a base substrate, the sensor being electrically connected to the base substrate and configured to sense biometric information, the sensor package further comprising an encapsulation part covering the base substrate and the sensor; and
a cap which is coupled to a side circumference of the sensor package and forms an insertion space part.

2. The fingerprint sensor module of claim 1, wherein a side surface of the base substrate is inclined such that a length from a virtual central axis of the base substrate is gradually increased from a lower portion of the base substrate to an upper portion of the base substrate.

3. The fingerprint sensor module of claim 1, wherein a stepped portion is formed in the encapsulation part.

4. The fingerprint sensor module of claim 1, wherein the cap and the base substrate are coupled in a state in which a lower portion of the base substrate partially protrudes from the cap to the insertion space part.

5. The fingerprint sensor module of claim 1, wherein the cap is made of a conductive material.

6. The fingerprint sensor module of claim 1, wherein the cap comprises a fixing part which is coupled to the sensor package; and a supporting part which is bent from the fixing part, forms the insertion space part, and supports the fixing part.

7. A fingerprint sensor module comprising:
a base substrate;
a sensor provided on an upper portion of the base substrate, the sensor being electrically connected to the base substrate and configured to sense biometric information; and
an encapsulation part covering the base substrate and the sensor,
wherein the encapsulation part has a keycap shape and forms an insertion space part below the base substrate.

8. The fingerprint sensor module of claim 7, wherein:
the encapsulation part comprises:
a cover member covering an upper surface of the base substrate and the sensor; and
a vertical member extending downward from an edge of the cover member and covering a side surface of the base substrate; and
the vertical member forms the insertion space part below the base substrate.

9. The fingerprint sensor module of claim 8, wherein fixing holes are formed at preset intervals along a circumference of the vertical member.

10. The fingerprint sensor module of claim 9, wherein guide protrusions each having a width corresponding to each of the fixing holes are formed on the base substrate.

11. The fingerprint sensor module of claim 7, wherein a height of the encapsulation part is greater than a height in which the base substrate and the sensor are coupled.

12. A method of manufacturing a fingerprint sensor module, the method comprising:
manufacturing a sensor package; and
coupling the sensor package and a cap.

13. The method of claim 12, wherein:
manufacturing a sensor package comprises forming an inclination at a side surface of a base substrate and forming a stepped portion in an encapsulation part provided on an upper portion of the base substrate and
the side surface of the base substrate is inclined such that a length from a virtual central axis is gradually increased from a lower portion of the base substrate to the upper portion of the base substrate.

14. The method of claim 12, wherein coupling the sensor package and a cap comprises:
fixing the sensor package to a molding die unit;
supplying a molding material into the molding die unit from a supply unit to mold the cap; and
coupling a side circumference of the sensor package and the cap.
